(19) United States
(12) Patent Application Publication
(10) Pub. No.: US 2024/0155806 A1
(43) Pub. Date: May 9, 2024

(54) SYSTEMS AND METHODS FOR CONFIGURING FAN SPEEDS

(71) Applicant: ATI Technologies ULC, Markham (CA)

(72) Inventors: Jabir H. Yusufali, Markham (CA); Ali Ebrahimi Khabbazi, Markham (CA); Cristian Andrei Saceleanu, Markham (CA); Jushwin Singh Mahal, Markham (CA)

(73) Assignee: ATI Technologies ULC, Markham (CA)

(21) Appl. No.: 17/980,377

(22) Filed: Nov. 3, 2022

(51) Int. Cl. H05K 7/20; F04D 27/00

(52) U.S. Cl. CPC H05K 7/20209; F04D 27/004

(57) ABSTRACT

The disclosed computer-implemented method for configuring fan speeds can include (i) measuring an air temperature at the air intake of a fan that cools a hardware processing unit of a computing device, (ii) adjusting a rotational speed for the fan based on the air temperature at the air intake of the fan and at least one additional parameter measured around the time of measuring the temperature of the air, and (iii) sending, to the fan, an instruction to rotate at the rotational speed. Various other methods, systems, and computer-readable media are also disclosed.

### BACKGROUND

Many computing devices, from personal computers to servers, rely on some form of cooling to prevent the heat generated by various computing components from causing undesirably high temperatures. Excessive heat and high temperatures can reduce system efficiency, for example by inducing higher static leakage and/or thermal throttling), and sometimes cause lasting damage to electronic components (i.e., by compromising reliability).

### BRIEF DESCRIPTION OF THE DRAWINGS

The accompanying drawings illustrate a number of non-limiting example implementations and are a part of the specification. Together with the following description, these drawings demonstrate and explain various principles of the present disclosure.

FIG. 1 is a block diagram of an example system for configuring fan speeds.

FIG. 2 is a flow diagram of an example method for configuring fan speeds.

FIG. 3 is a block diagram of an example system for configuring fan speeds.

FIG. 4 is an illustration of an example fan with a temperature sensor.

Throughout the drawings, identical reference characters and descriptions indicate similar, but not necessarily identical, elements. While the non-limiting example implementations described herein are susceptible to various modifications and alternative forms, specific implementations have been shown by way of non-limiting example in the drawings and will be described in detail herein. However, the non-limiting example implementations described herein are not intended to be limited to the particular forms disclosed. Rather, the present disclosure covers all modifications, equivalents, and alternatives falling within the scope of the appended claims.

### DETAILED DESCRIPTION OF NON-LIMITING EXAMPLE IMPLEMENTATIONS

One of the most common methods of cooling uses fans to move relatively cooler air over the hot surfaces of various components, drawing heat out of those components and dispersing it into the surrounding environment. However, operating fans both consume power and generate noise which can be undesirable in constrained systems such as desktop chassis and laptops. Consequently, computing devices have systems that attempt to keep a fan running at the optimal speed. Traditional systems for controlling fan speed typically base the fan speed solely on an estimate of component temperature. Some traditional systems can have a hard-coded table of correspondences between component temperature and fan speed. For example, these systems can increase fan speed (and thereby airflow) as the temperature of the component increases. However, this technique frequently results in inefficient cooling as well as excess power consumption and suboptimal noise generation. The instant disclosure therefore identifies and addresses a need for systems and methods for controlling cooling fans.

The present disclosure is generally directed to systems and methods for configuring fan speeds by adjusting fan speed based on the temperature at the air intake and/or other relevant parameters. By using the temperature of the air at the intake to calculate the optimal fan speed, rather than basing the fan speed solely on the temperature of the hardware to be cooled, the systems described herein can balance the downsides of elevated fan speed (noise, etc.) with maintaining a sufficiently cool temperature for various hardware components in various operating environments. In some implementations, the systems described herein can improve the functioning of a computing device by optimizing the cooling hardware components of the computing device, avoiding suboptimal noise, inefficiency and/or component damage due to overheating. In some implementations, the systems described herein can improve the field of hardware cooling by configuring fan speeds to cool hardware.

A method for cooling hardware processing units can include (i) measuring an air temperature at the air intake of a fan that cools a hardware processing unit of a computing device, (ii) adjusting a rotational speed for the fan based on the air temperature at the air intake of the fan and at least one additional parameter measured around the time of measuring the temperature of the air, and (iii) sending, to the fan, an instruction to rotate at the rotational speed. The method can include additional steps such as measuring the air temperature via a temperature sensor located at the air intake of the fan.

In some non-limiting examples, adjusting the rotational speed for the fan based on the air temperature at the air intake can include increasing the rotational speed for the fan above a current rotational speed of the fan in response to detecting that the air temperature has surpassed an ambient temperature threshold. In further non-limiting examples, adjusting the rotational speed for the fan based on the air temperature at the air intake can include decreasing the rotational speed for the fan below a current rotational speed of the fan in response to detecting that the air temperature has decreased below an ambient temperature threshold.

In some implementations, the hardware processing unit can include an internal thermometer that measures a temperature of the hardware processing unit. In these implementations, the additional parameter can include the temperature of the hardware processing unit.

The additional parameter(s) can additionally or alternatively include a variety of other information. For example, the additional parameter(s) can include a current electrical power usage of the hardware processing unit. In further non-limiting examples, the additional parameter(s) can include an expected acoustic output of the fan at the rotational speed. Additionally or alternatively, the additional parameter(s) can include both a current electrical power usage of the hardware processing unit and a temperature of the hardware processing unit.

In some non-limiting examples, the method can include (i) detecting that at least one of a hardware processing unit temperature and/or the air temperature has surpassed a temperature threshold and (ii) displaying an alert to a user that at least one of the hardware processing unit temperature and/or the air temperature has surpassed the temperature threshold.

In some implementations, the method can also include displaying a graphical user interface on a display of the computing device that includes the air temperature at the air intake of the fan.

In one implementation, an apparatus for configuring fan speeds can include (i) a fan that cools a hardware processing unit of a computing device, (ii) a thermometer positioned at an air intake for the fan that measures a temperature of air at the air intake, and (iii) a computing module that adjusts a rotational speed for the fan based on the temperature of the air at the air intake and at least one additional parameter measured around the time of measuring the temperature of the air. In some implementations, the computing module can direct the fan to rotate at the rotational speed.

In some non-limiting examples, the hardware processing unit can include an internal thermometer that measures a temperature of the hardware processing unit. In these non-limiting examples, the additional parameter can include the temperature of the hardware processing unit.

The additional parameter(s) can additionally or alternatively include a variety of other information. For example, the additional parameter(s) can include a current electrical power usage of the hardware processing unit. In further non-limiting examples, the additional parameter(s) can include an expected acoustic output of the fan at the rotational speed.

The hardware processing unit can likewise include a variety of computing hardware. For example, the hardware processing unit can include the computing module. In other non-limiting examples, the hardware processing unit can include a central processing unit for the computing device. Additionally or alternatively, the hardware processing unit can include a hardware accelerator.

A system for configuring fan speeds can include (i) a hardware processing unit that includes an internal thermometer that measures a temperature of the hardware processing unit and that provides at least one of computational processing or graphical processing for a computing device, (ii) a fan positioned within the computing device such that the fan cools the hardware processing unit, (iii) a thermometer positioned at an air intake for the fan that measures a temperature of air at the air intake, and (iv) a computing module that adjusts a rotational speed for the fan based on the temperature of the air at the air intake and the temperature of the hardware processing unit.

Features from any of the implementations described herein can be used in combination with one another in accordance with the general principles described herein. These and other implementations, features, and advantages will be more fully understood upon reading the following detailed description in conjunction with the accompanying drawings and claims.

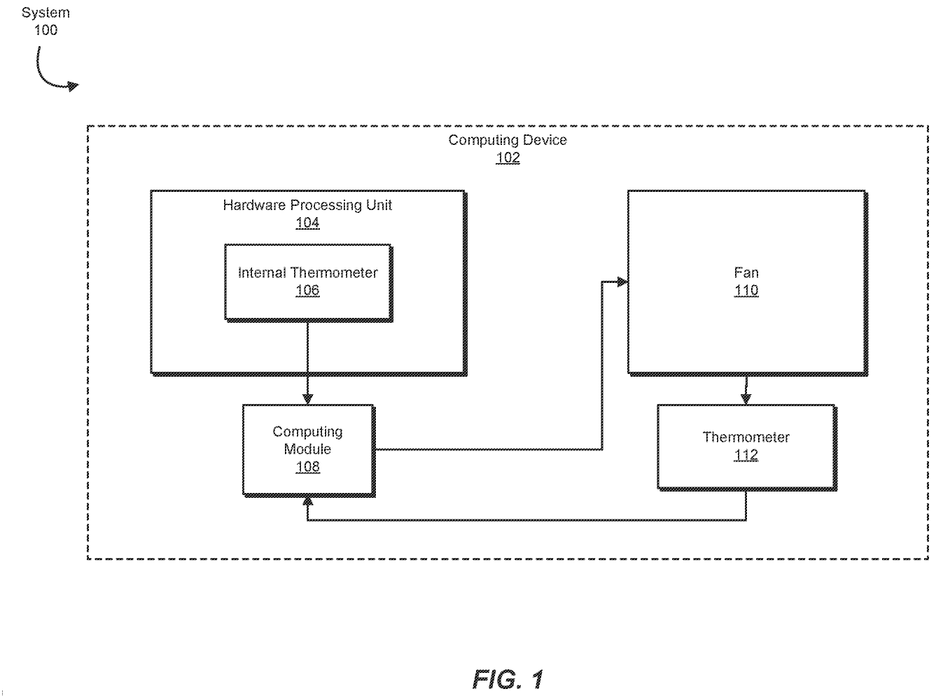

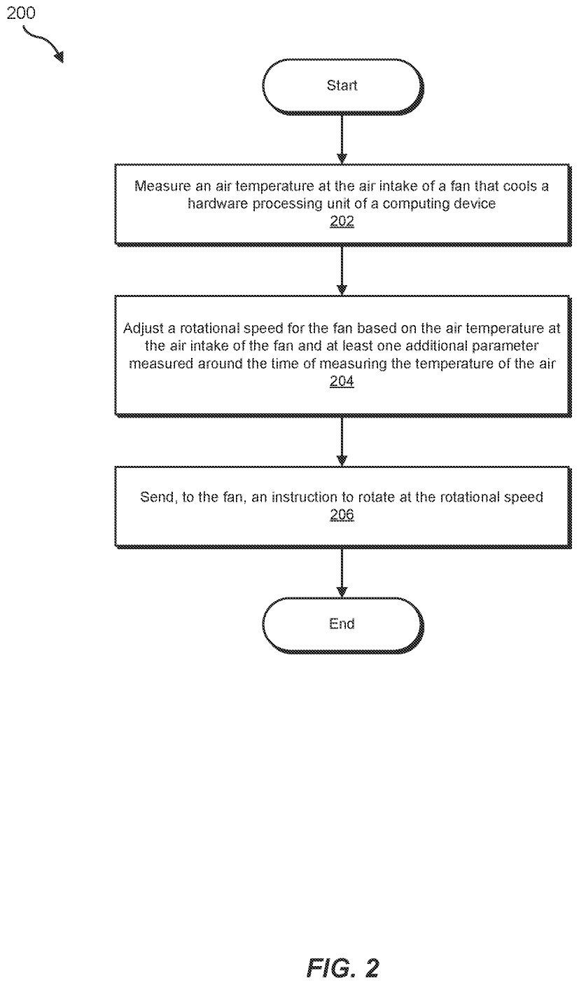

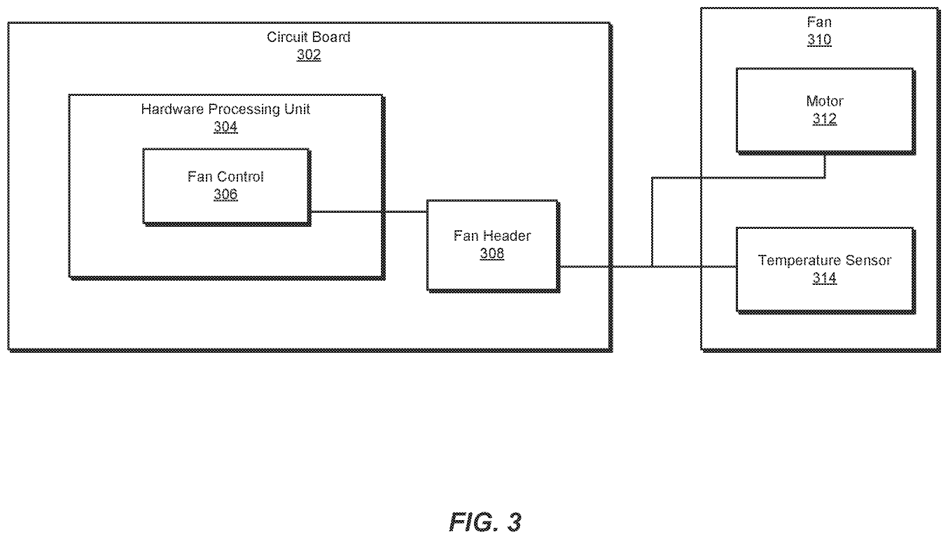

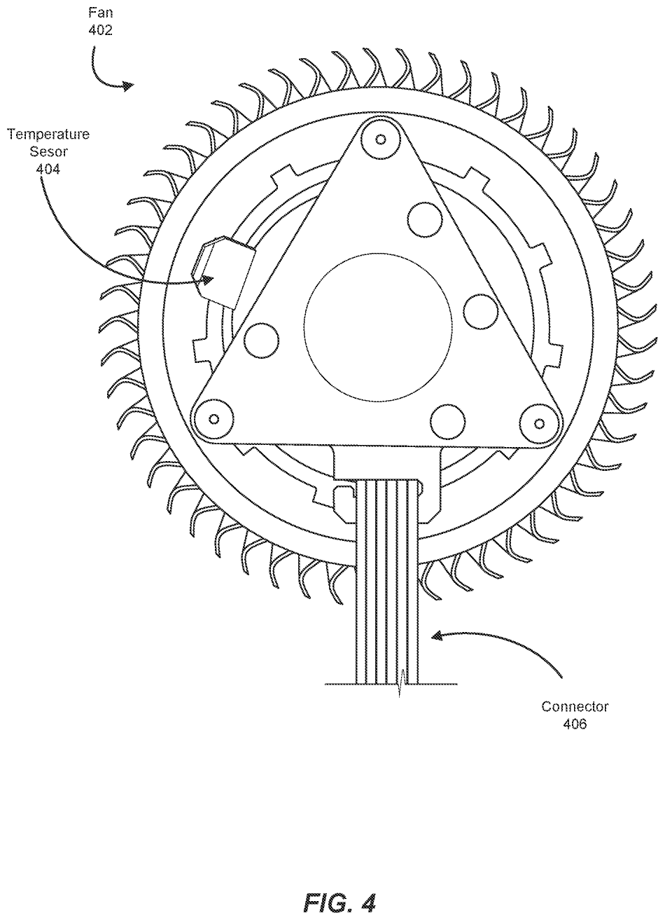

The following will provide, with reference to FIGS. 1 and 3, detailed descriptions of non-limiting example systems for configuring fan speeds. Detailed descriptions of corresponding computer-implemented methods will also be provided in connection with FIG. 2. In addition, detailed descriptions of a non-limiting example fan will be provided in connection with FIG. 4.

System 100 is an exemplary system for controlling fan speeds based at least in part on the temperature of air at a fan air intake. In one implementation, a computing device 102 can be configured with a fan 110 that cools a hardware processing unit 104 of computing device 102. In some implementations, a thermometer 112 positioned at an air intake for fan 110 can measure the temperature of air at the air intake. In one implementation, a computing module 108 can adjust a rotational speed for fan 100 based on the temperature of the air at the air intake and/or at least one additional parameter measured around the time of measuring the temperature of the air. For example, an additional parameter can be a temperature of hardware processing unit 104 measured by an internal thermometer 106.

Computing device 102 generally represents any type or form of computing device capable of reading computer-executable instructions. In one implementation, computing device 102 can be a personal computing device operated by an end user. Additional non-limiting examples of computing device 102 include, without limitation, laptops, tablets, desktops, servers, cellular phones, Personal Digital Assistants (PDAs), multimedia players, embedded systems, wearable devices (e.g., smart watches, smart glasses, etc.), smart vehicles, so-called Internet-of-Things devices (e.g., smart appliances, etc.), gaming consoles, variations or combinations of one or more of the same, or any other suitable computing device.

Hardware processing unit 104 can generally represent any type of computing hardware that produces heat during operation. In some implementations, a hardware processing unit can include a central processing unit (CPU) That performs a variety of computational functions for a computing device. Additionally or alternatively, a hardware processing unit can include a hardware accelerator that is designed to perform a specific function efficiently. For example, a hardware accelerator unit can include a graphics processing unit (GPU) that performs graphical processing functions for a computing device. In some implementations, a GPU can be a separate component from other computing components (e.g., a motherboard, CPU, etc.) that can be inserted into a computer case and/or physically connected to other computing components. In some implementations, a fan associated with a hardware processing unit can be physically connected to the hardware processing unit. For example, an installable GPU card can come with an onboard fan.

Computing module 108 generally represents any type or form of hardware, software, and/or firmware module capable of processing computer-executable instructions. In one implementation, a computing module can be part of a hardware processing unit, such as part of a GPU card. Additionally or alternatively, a computing module can be part of a computing device.

The term thermometer, as used herein, can generally refer to any type of sensor capable of measuring temperature. In one implementation, a thermometer can include a temperature-sensitive diode, thermistor, bipolar junction transistor, and/or an integrated circuit. Thermometer 112 generally represents any thermometer positioned at an air intake for a fan or computing device. Internal thermometer 106 generally represents any thermometer positioned such that the thermometer can measure the thermal state of a hardware processing unit. In one implementation, internal thermometer 106 may be located inside a casing of a hardware processing unit.

Many other devices or subsystems can be connected to system 100 in FIG. 1. Conversely, all of the components and devices illustrated in FIG. 1 need not be present to practice the implementations described and/or illustrated herein. The devices and subsystems referenced above can also be interconnected in different ways from that shown in FIG. 1. System 100 can also employ any number of software, firmware, and/or hardware configurations. For example, one or more of the non-limiting example implementations disclosed herein can be encoded as a computer program (also referred to as computer software, software applications, computer-readable instructions, and/or computer control logic) on a computer-readable medium.

The term “computer-readable medium,” as used herein, generally refers to any form of device, carrier, or medium capable of storing or carrying computer-readable instructions. Non-limiting examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

FIG. 2 is a flow diagram of an example computer-implemented method 200 for configuring fan speeds. The steps shown in FIG. 2 can be performed by any suitable computer-executable code and/or computing system, including system 100 in FIG. 1 and/or variations or combinations of one or more of the same. In one non-limiting example, each of the steps shown in FIG. 2 can represent an algorithm whose structure includes and/or is represented by multiple sub-steps, non-limiting examples of which will be provided in greater detail below.

As illustrated in FIG. 2, at step 202 one or more of the systems described herein can measure the air temperature at the air intake of a fan that cools a hardware processing unit of a computing device. For example, thermometer 112 can measure air temperature at the air intake of fan 110 that cools hardware processing unit 104 of computing device 102.

The systems described herein can perform step 202 in a variety of ways and/or contexts. In one non-limiting example, a thermometer can be coupled to a fan such that the thermometer is positioned next to the air intake of the fan. In another implementation, a thermometer can be attached to a computer case, positioned such that if a hardware processing unit (e.g., a graphics card) with a fan is placed within the computer case, the thermometer is positioned at the air intake for the fan. In one implementation, a thermometer can read temperature into memory, communicate to controller in real time, and/or respond to real-time commands from the controller.

At step 204 one or more of the systems described herein can adjust a rotational speed for the fan based on the air temperature at the air intake of the fan and at least one additional parameter measured around the time of measuring the temperature of the air. For example, computing module 108 can adjust a rotational speed for fan 110 based on the air temperature at the air intake of fan 110 and at least one additional parameter.

The term rotational speed can generally refer to any measurement of the speed of a fan as the fan rotates. In one implementation, the systems described herein may measure and/or store rotational speed as rotations per minute (i.e., a number representing the amount of full rotations the blades of the fan perform in one minute). The phrase “around the time” can generally refer to any actions taken within a specified, narrow window of time of one another. For example, two parameters can be measured around the time of one another if the two parameters are measured simultaneously, if the two parameters are measured within ten milliseconds of one another, if the two parameters are measured within the same second, and/or if the two parameters are measured within the same minute.

The systems described herein can adjust the rotational speed for the fan in a variety of ways. For example, the systems described herein can calculate the rotational speed based on a combination of the temperature at the air intake, the temperature of the hardware processing unit, an expected acoustic output of the fan at the rotational speed, and/or electrical power currently being consumed by the hardware processing unit. The systems described herein can estimate expected acoustic output (i.e., the acoustic output the fan will produce at the new speed) in a variety of ways, such as referencing historical data for the sound and/or vibrations produced by the fan (e.g., as measured in decibels) at various speeds in the past, referencing manufacturer data about acoustic output under various conditions, and/or measuring the current acoustic output of the fan and calculating the expected output based at least in part on the current output. In some examples, the systems described herein can measure the electrical power currently being consumed by the hardware processing unit by measuring volts and/or amperage at one or more physical locations on the hardware unit (e.g., on a junction, on wires leading to and/or from the unit, etc.). The systems described herein can dynamically calculate a fan speed based on existing conditions rather than referencing a predetermined, hard-coded table.

In some non-limiting examples, calculating the rotational speed can result in increasing the rotational speed for the fan above a current rotational speed of the fan in response to detecting that the air temperature has surpassed an ambient temperature threshold. In other non-limiting examples, calculating the rotational speed can result in decreasing the rotational speed for the fan below a current rotational speed of the fan in response to detecting that the air temperature has decreased below an ambient temperature threshold. The term ambient temperature threshold generally refers to any pre-defined threshold for the temperature of an environment around a computing device (e.g., the room in which a device is located).

At step 206 one or more of the systems described herein can send, to the fan, an instruction to rotate at the rotational speed. For example, computing module 108 can send, to fan 110, an instruction to rotate at the rotational speed.

The systems described herein can send an instruction to the fan in a variety of ways. For example, the systems described herein can include a bidirectional communication link between the fan and the computing module. In some implementations, the systems described herein can send an instruction to a fan that is built in to a graphics card. Additionally or alternatively, in some non-limiting examples, the systems described herein can send an instruction to an external fan or thermal solution, such as a fan on a server that includes the graphics card. In some non-limiting examples, the systems described herein can include a passively cooled graphics card that is cooled by a thermal solution on a server in which the graphics card is installed and the systems described herein may use a measurement of temperature at an air intake and/or other parameters to formulate a suggestion to the external thermal solution.

In some implementations, the systems described herein can include a circuit board. For example, as illustrated in FIG. 3, a circuit board 302 can be coupled to a hardware processing unit 304 that includes a fan control 306 and/or a fan header 308. In one implementation, fan header 308 can be communicatively coupled to a fan 310 that includes a motor 312 and a temperature sensor 314. In one implementation, fan control 306 can communicate with fan header 308 that communicates with motor 312 and/or temperature sensor 314. For example, fan header 308 can receive temperature data from temperature sensor 314 and pass this temperature data on top fan control 306 which can respond with instructions to speed up or slow down motor 312 that are passed to motor 312 via fan header 308. In one implementation, fan header 308 can have pins for clock and data in addition to pins for reading and controlling the speed of motor 312. In some implementations, fan control 306 can be a computing module configured with code for calculating rotational speed for motor 312 based on various parameters including the temperature of air at an air intake for fan 310 as measured by temperature sensor 314.

In some implementations, the systems described herein can notify a user about one or more of the parameters measured by the systems discussed herein. For example, in response to detecting an elevated temperature at a fan air intake (e.g., a temperature that exceeds a predetermined threshold), the systems described herein can alert a user that the air intake temperature is high and/or can suggest that the user takes steps to mitigate this temperature, such as by opening a computer case that houses the fan. The systems described herein can notify a user in a variety of ways, such as via a pop-up notification, a notification within a hardware monitoring app, and/or a visual overlay. In some implementations, the systems described herein can display a graphical user interface on a display of the computing device that includes the temperature of the air at the air intake, the temperature of the hardware processing unit, and/or other relevant information about the fan and/or hardware processing unit.

In some implementations, a temperature sensor at a fan air intake can be directly coupled to a fan. For example, as illustrated in FIG. 4, a temperature sensor 404 can be directly coupled to a fan 402. In some implementations, temperature sensor 404 can be located on and/or part of a printed circuit board component of fan 402. In one implementation, fan 402 can include a connector 406 that connects fan 402 to a hardware processing unit. For example, connector 406 can include one or more cables (e.g., rubber-coated metal wires or bundles of metal wires).

While the foregoing disclosure sets forth various implementations using specific block diagrams, flowcharts, and non-limiting examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered non-limiting example in nature since many other architectures can be implemented to achieve the same functionality.

In some non-limiting examples, all or a portion of example system 100 in FIG. 1 can represent portions of a cloud-computing or network-based environment. Cloud-computing environments can provide various services and applications via the Internet. These cloud-based services (e.g., software as a service, platform as a service, infrastructure as a service, etc.) can be accessible through a web browser or other remote interface. Various functions described herein can be provided through a remote desktop environment or any other cloud-based computing environment.

In various implementations, all or a portion of example system 100 in FIG. 1 can facilitate multi-tenancy within a cloud-based computing environment. In other words, the modules described herein can configure a computing system (e.g., a server) to facilitate multi-tenancy for one or more of the functions described herein. For example, one or more of the modules described herein can program a server to enable two or more clients (e.g., customers) to share an application that is running on the server. A server programmed in this manner can share an application, operating system, processing system, and/or storage system among multiple customers (i.e., tenants). One or more of the modules described herein can also partition data and/or configuration information of a multi-tenant application for each customer such that one customer cannot access data and/or configuration information of another customer.

According to various implementations, all or a portion of example system 100 in FIG. 1 can be implemented within a virtual environment. For example, the modules and/or data described herein can reside and/or execute within a virtual machine. As used herein, the term “virtual machine” generally refers to any operating system environment that is abstracted from computing hardware by a virtual machine manager (e.g., a hypervisor).

In some non-limiting examples, all or a portion of example system 100 in FIG. 1 can represent portions of a mobile computing environment. Mobile computing environments can be implemented by a wide range of mobile computing devices, including mobile phones, tablet computers, e-book readers, personal digital assistants, wearable computing devices (e.g., computing devices with a head-mounted display, smartwatches, etc.), variations or combinations of one or more of the same, or any other suitable mobile computing devices. In some non-limiting examples, mobile computing environments can have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein can be provided for a mobile computing environment and/or can interact with a mobile computing environment.

The process parameters and sequence of steps described and/or illustrated herein are given by way of non-limiting example only and can be varied as desired. For example, while the steps illustrated and/or described herein can be shown or discussed in a particular order, these steps do not necessarily need to be performed in the order illustrated or discussed. The various non-limiting example methods described and/or illustrated herein can also omit one or more of the steps described or illustrated herein or include additional steps in addition to those disclosed.

While various implementations have been described and/or illustrated herein in the context of fully functional computing systems, one or more of these non-limiting example variations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the non-limiting example implementations disclosed herein.

The preceding description has been provided to enable others skilled in the art to best utilize various aspects of the non-limiting example implementations disclosed herein. This non-limiting example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A method comprising:
measuring an air temperature at the air intake of a fan that cools a hardware processing unit of a computing device;
adjusting a rotational speed for the fan based on the air temperature at the air intake of the fan and at least one additional parameter measured around the time of measuring the temperature of the air; and
sending, to the fan, an instruction to rotate at the rotational speed.

2. The method of claim 1, wherein measuring the air temperature comprises measuring the air temperature via a temperature sensor located at the air intake of the fan.

3. The method of claim 1, wherein adjusting the rotational speed for the fan based on the air temperature at the air intake comprises increasing the rotational speed for the fan above a current rotational speed of the fan in response to detecting that the air temperature has surpassed an ambient temperature threshold.

4. The method of claim 1, wherein adjusting the rotational speed for the fan based on the air temperature at the air intake comprises decreasing the rotational speed for the fan below a current rotational speed of the fan in response to detecting that the air temperature has decreased below an ambient temperature threshold.

5. The method of claim 1, wherein the hardware processing unit comprises an internal thermometer that measures a temperature of the hardware processing unit; and
the at least one additional parameter comprises the temperature of the hardware processing unit.

6. The method of claim 1, wherein the at least one additional parameter comprises a current electrical power usage of the hardware processing unit.

7. The method of claim 1, wherein the at least one additional parameter comprises an expected acoustic output of the fan at the rotational speed.

8. The method of claim 1, wherein the at least one additional parameter comprises a current electrical power usage of the hardware processing unit and a temperature of the hardware processing unit.

9. The method of claim 1, further comprising:
detecting that at least one of a hardware processing unit temperature and the air temperature has surpassed a temperature threshold; and
displaying an alert to a user that at least one of the hardware processing unit temperature and the air temperature has surpassed the temperature threshold.

10. The method of claim 1, further comprising displaying a graphical user interface on a display of the computing device that comprises the air temperature at the air intake of the fan.

11. An apparatus comprising:
a fan that cools a hardware processing unit of a computing device;
a thermometer positioned at an air intake for the fan that measures a temperature of air at the air intake; and
a computing module that adjusts a rotational speed for the fan based on the temperature of the air at the air intake and at least one additional parameter measured around the time of measuring the temperature of the air.

12. The apparatus of claim 11, wherein the hardware processing unit comprises an internal thermometer that measures a temperature of the hardware processing unit; and
the at least one additional parameter comprises the temperature of the hardware processing unit.

13. The apparatus of claim 11, wherein the at least one additional parameter comprises a current electrical power usage of the hardware processing unit.

14. The apparatus of claim 11, wherein the at least one additional parameter comprises an expected acoustic output of the fan at the rotational speed.

15. The apparatus of claim 11, wherein the hardware processing unit comprises the computing module.

16. The apparatus of claim 11, wherein the hardware processing unit comprises a central processing unit for the computing device.

17. The apparatus of claim 11, the hardware processing unit comprises a hardware accelerator.

18. The apparatus of claim 11, wherein the computing module directs the fan to rotate at the rotational speed.

19. A non-transitory computer-readable medium comprising one or more computer-readable instructions that, when executed by at least one processor of a computing device, cause the computing device to:
measure an air temperature at the air intake of a fan that cools a hardware processing unit of a computing device;
adjust a rotational speed for the fan based on the air temperature at the air intake of the fan and at least one additional parameter measured around the time of measuring the temperature of the air; and
send, to the fan, an instruction to rotate at the rotational speed.

20. The non-transitory computer-readable medium of claim 19, wherein adjusting the rotational speed for the fan is based on the temperature of the air at the air intake, the temperature of the hardware processing unit, and a current electrical power usage of the hardware processing unit.
